(19) United States
(12) Patent Application Publication
(10) Pub. No.: US 2025/0113707 A1
(43) Pub. Date: Apr. 3, 2025

(54) DISPLAY PANEL AND DISPLAY DEVICE

(71) Applicant: HKC CORPORATION LIMITED, SHENZHEN (CN)

(72) Inventors: Zhi YANG, SHENZHEN (CN); Xiufeng ZHOU, SHENZHEN (CN); Yangling TANG, SHENZHEN (CN); Zhisheng XIE, SHENZHEN (CN); Hailang WANG, SHENZHEN (CN); Lidan YE, SHENZHEN (CN)

(73) Assignee: HKC CORPORATION LIMITED, SHENZHEN (CN)

(21) Appl. No.: 18/888,168

(22) Filed: Sep. 18, 2024

(30) Foreign Application Priority Data
Sep. 28, 2023 (CN) 202311279772.9

(51) Int. Cl. H10K 59/122; H10K 59/131; H10K 59/35

(52) U.S. Cl. CPC H10K 59/122; H10K 59/131; H10K 59/352; H10K 59/353

(57) ABSTRACT

A display panel and a display device. The display panel includes: a driving substrate, a pixel defining layer, and repeating units. Each repeating unit includes: an electrically conductive isolation structure, including a first electrically conductive isolation structure and a second electrically conductive isolation structure; wherein the first electrically conductive isolation structure forms a first pixel holding region and a second pixel holding region; a side of the second electrically conductive isolation structure toward the first electrically conductive isolation structure is formed with a third pixel holding region. In each repeating unit, a cathode of each sub-pixel is in contact and electrically conductive with the first electrically conductive isolation structure; the second electrically conductive isolation structure extends along a first direction, and multiple repeating units are arranged in an array along the first direction; the multiple repeating units are electrically connected to each other and accessed to a same electrical signal.

### CROSS REFERENCE

The present disclosure claims priority of Chinese Patent Application No. 202311279772.9, filed on Sep. 28, 2023, the entire contents of which are hereby incorporated by reference in their entirety.

### TECHNICAL FIELD

The present disclosure relates to the field of display technologies, and more specifically to a display panel and a display device.

### BACKGROUND

Organic Light-Emitting Diode (OLED), compared to the current mainstream flat panel display technology, has advantages such as high contrast, wide viewing angle, low power consumption, thinner volume, etc.

However, due to its own characteristics such as production process and pixel arrangement, there are still some urgent problems for the OLED screen. The limitations of the existing pixel arrangement structure may cause jaggedness or colored edges when the pixel arrangement structure displays a specific pattern such as text and lines in a certain direction, which affects the display effect. In addition, due to the restriction of Fine Metal Mask (FMM) used for vaporizing R/G/B pixels, there are limits to the shape of the pixels and the distance between pixels, thus limiting the opening ratio of the display panel.

### SUMMARY OF THE DISCLOSURE

The main technical problem solved by the present disclosure is to provide a display panel and a display device.

To solve the above technical problems, the present disclosure provides a display panel, including:
a driving substrate;
a pixel defining layer, arranged on a side of the driving substrate; and
a plurality of repeating units; wherein each repeating unit includes:
an electrically conductive isolation structure, including a first electrically conductive isolation structure and a second electrically conductive isolation structure electrically connected to each other; wherein the first electrically conductive isolation structure protrudes out of the pixel defining layer and encloses to form a first pixel holding region and a second pixel holding region that are spaced apart; the second electrically conductive isolation structure is disposed on at least one side of the first electrically conductive isolation structure, and a side of the second electrically conductive isolation structure toward the first electrically conductive isolation structure is formed with a third pixel holding region at least partially enclosing the first electrically conductive isolation structure; and
a pixel unit, including three sub-pixels having different colors; wherein the three sub-pixels are disposed in a one-to-one correspondence in the first pixel holding region, the second pixel holding region, and the third pixel holding region formed in the electrically conductive isolation structure;
wherein in each repeating unit, a cathode of each of the three sub-pixels is in contact and electrically conductive with the first electrically conductive isolation structure; the second electrically conductive isolation structure extends along a first direction, and multiple of the plurality of repeating units are arranged in an array along the first direction; the multiple of the plurality of repeating units are electrically connected to each other through the second electrically conductive isolation structures and accessed to a same electrical signal.

To solve the above technical problems, the present disclosure further provides a display device, including the display panel as above.

### BRIEF DESCRIPTION OF THE DRAWINGS

In order to more clearly illustrate the technical solutions in the embodiments of the present disclosure, the accompanying drawings to be used in the description of the embodiments will be briefly introduced below, and it will be obvious that the accompanying drawings in the following description are only some of the embodiments of the present disclosure, and other accompanying drawings can be obtained according to these drawings for the those skilled in the art, without any creative labor.

FIG. 1 is a structural schematic view of a display panel according to a first implementation of the present disclosure.

FIG. 2 is a schematic structural view of a repeating unit in FIG. 1.

FIG. 3 is a cross-sectional structural schematic view along E-E in FIG. 1.

FIG. 4 is a schematic structural view of a first electrically conductive isolation structure and a sub-pixel according to a first embodiment of the present disclosure.

FIG. 5a is a schematic structural view of a first electrically conductive isolation structure and a sub-pixel according to a second embodiment of the present disclosure.

FIG. 5b is a schematic structural view of a first electrically conductive isolation structure and a sub-pixel according to a third embodiment of the present disclosure.

FIG. 5c is a schematic structural view of a first electrically conductive isolation structure and a sub-pixel according to a fourth embodiment of the present disclosure.

FIG. 5d is a schematic structural view of a first electrically conductive isolation structure and a sub-pixel according to a fifth embodiment of the present disclosure.

FIG. 5e is a schematic structural view of a first electrically conductive isolation structure and a sub-pixel according to a sixth embodiment of the present disclosure.

FIG. 5f is a schematic structural view of a first electrically conductive isolation structure and a sub-pixel according to a seventh embodiment of the present disclosure.

FIG. 6 is a structural schematic view of a display panel according to a second implementation of the present disclosure.

FIG. 7 is a structural schematic view of a display panel according to a third implementation of the present disclosure.

FIG. 8 is a cross-sectional structural schematic view along F-F in FIG. 7.

FIG. 9a is a structural schematic view of a display panel according to a fourth implementation of the present disclosure.

FIG. 9b is a structural schematic view of a display panel according to a fifth implementation of the present disclosure.

FIG. 10 is a structural schematic view of a display panel according to a sixth implementation of the present disclosure.

FIG. 11 is a cross-sectional structural schematic view along G-G in FIG. 10.

FIG. 12 is a structural schematic view of a display panel according to a seventh implementation of the present disclosure.

FIG. 13 is a cross-sectional structural schematic view along H-H in FIG. 12.

FIG. 14 is a structural schematic view of a display panel according to an eighth implementation of the present disclosure.

### DETAILED DESCRIPTION

The following description, in conjunction with the accompanying drawings of the specification, provides a detailed description of the program of embodiments of the present disclosure.

In the following description, specific details such as particular system structures, interfaces, techniques, and the like are presented for the purpose of illustration and not for limitation, in order to provide a thorough understanding of the present disclosure.

The technical solutions in the embodiments of the present disclosure will be clearly and completely described below in conjunction with the accompanying drawings in the embodiments of the present disclosure, and it is clear that the described embodiments are only a part of the embodiments of the present disclosure, and not all of the embodiments. Based on the embodiments in the present disclosure, all other embodiments obtained by those skilled in the art without creative labor fall within the scope of the present disclosure.

The terms of “first”, “second”, and “third” in the present disclosure are intended for descriptive purposes only, and are not to be construed as indicating or implying relative importance or implicitly specifying the number of technical features indicated. Thus, a feature defined with “first”, “second”, “third” may include at least one such feature, either explicitly or implicitly. In the description of the present disclosure, “plurality” means at least two, e.g., two, three, etc., unless otherwise expressly and specifically limited. All directional indications (e.g., up, down, left, right, forward, backward . . . ) in the embodiments of the present disclosure are only intended to explain the relative positional relationship, movement, etc. between components in a particular attitude (as shown in the accompanying drawings), and the directional indications are changed accordingly if the particular attitude is changed. Furthermore, the terms “including” and “having” and any variations thereof are intended to cover non-exclusive inclusion. For example, a process, method, system, product or apparatus comprising a series of steps or units is not limited to the listed steps or units, but optionally further includes steps or units that are not listed, or optionally includes other steps or units that are inherent to the process, method, product or apparatus.

Reference to “embodiments” herein means that particular features, structures, or characteristics described in conjunction with the embodiments may be included in at least one embodiment of the present disclosure. The presence of the phrase at various points in the specification does not necessarily refer to the same embodiments or to separate or alternative embodiments that are mutually exclusive of other embodiments. It is understood by those skilled in the art, both explicitly and implicitly, that the embodiments described herein may be combined with other embodiments.

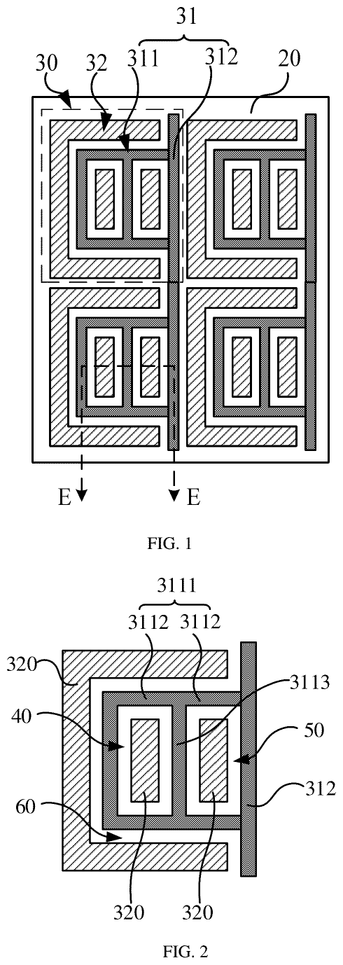

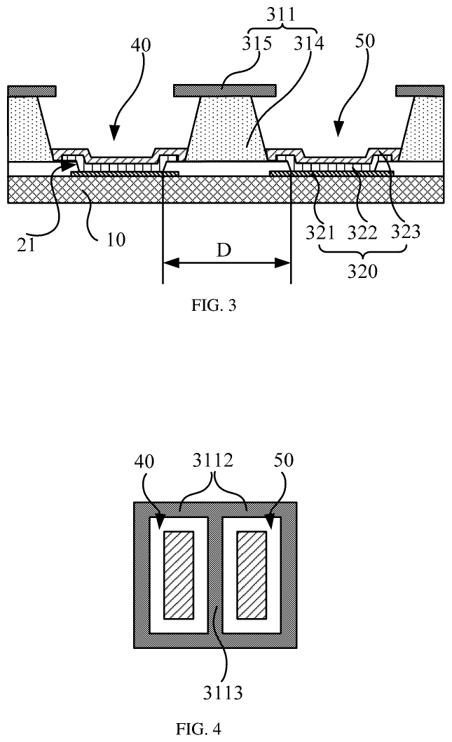

Referring to FIGS. 1 to 4, FIG. 1 is a structural schematic view of a display panel according to a first implementation of the present disclosure, FIG. 2 is a schematic structural view of a repeating unit in FIG. 1, FIG. 3 is a cross-sectional structural schematic view along E-E in FIG. 1, and FIG. 4 is a schematic structural view of a first electrically conductive isolation structure and a sub-pixel according to a first embodiment of the present disclosure.

The present disclosure provides a display panel. The display panel includes a driving substrate 10, a pixel defining layer 20, and multiple repeating units 30. The pixel defining layer 20 is arranged on a side of the driving substrate 10. Each repeating unit 30 includes an electrically conductive isolation structure 31 and a pixel unit 32. The electrically conductive isolation structure 31 includes a first electrically conductive isolation structure 311 and a second electrically conductive isolation structure 312 electrically connected to each other. The first electrically conductive isolation structure 311 protrudes out of the pixel defining layer 20 and encloses to form a first pixel holding region 40 and a second pixel holding region 50 that are spaced apart. The second electrically conductive isolation structure 312 is disposed on at least one side of the first electrically conductive isolation structure 311, and a side of the second electrically conductive isolation structure 312 toward the first electrically conductive isolation structure 311 is formed with a third pixel holding region 60 at least partially enclosing the first electrically conductive isolation structure 311. The pixel unit 32 includes three sub-pixels 320 having different colors, and the three sub-pixels 320 having different colors are disposed in a one-to-one correspondence in the three pixel holding regions formed in the electrically conductive isolation structure 31. In each repeating unit 30, a cathode 323 of each of the three sub-pixels 320 is in contact and electrically conductive with the first electrically conductive isolation structure 311. The second electrically conductive isolation structure 312 extends along a first direction, and multiple repeating units 30 are arranged in an array along the first direction. The multiple repeating units 30 are electrically connected to each other through the second electrically conductive isolation structures 312 and accessed to a same electrical signal.

In the present disclosure, a side of the second electrically conductive isolation structure 312 toward the first electrically conductive isolation structure 311 is formed with the third pixel holding region 60 at least partially enclosing the first electrically conductive isolation structure 311, and the first electrically conductive isolation structure 311 encloses to form the first pixel holding region 40 and the second pixel holding region 50 that are spaced apart, such that the third pixel holding region 60 can at least partially surround the first pixel holding region 40 and the second pixel holding region 50, such that the sub-pixel 320 disposed in the third pixel holding region 60 can at least partially enclose the sub-pixel 320 disposed in the first pixel holding region 40 and the sub-pixel 320 disposed in the second pixel holding region 50, which in turn may mitigate the problem of colored edges of the display panel. Furthermore, in each repeating unit 30, the cathodes 323 of the sub-pixels 320 are all in contact and electrically conductive with the first electrically conductive isolation structure 311, thereby realizing mutual electrical connection between the first electrically conductive isolation structure 311 and the cathodes 323 of the multiple sub-pixels 320, and between the first electrically conductive isolation structure 311 and the second electrically conductive isolation structure 312; further, in the extending direction of the second electrically conductive isolation structure 312, the second electrically conductive isolation structures 312 in the multiple repeating units 30 are electrically connected to each other and accessed to the same electrical signal, thereby enabling the cathodes 323 of all sub-pixels 320 to access to the same electrical signal through the second electrically conductive isolation structures 312. In addition, due to the less width of the electrically conductive isolation structure 31, the spacing between the sub-pixels 320 may be less compared to a manufacturing process using a fine metal mask plate in the related art, thereby enhancing the pixel opening ratio of the display panel.

It should be noted that the first pixel holding region 40, the second pixel holding region 50, and the third pixel holding region 60 of the present disclosure are all pixel holding regions, only that the colors of the sub-pixels 320 held in each of the first pixel holding region 40, the second pixel holding region 50, and the third pixel holding region 60 are different, as well as the positions at which each of them is located are different.

The driving substrate 10 is configured to drive the sub-pixel 320 within the pixel unit 32 to emit light.

The sub-pixel 320 includes an anode 321, a light emitting layer 322, and a cathode 323 sequentially cascaded on the side of the driving substrate 10. The pixel defining layer 20 is configured to limit the positions of the sub-pixels 320 and to isolate the anodes 321 of the sub-pixels 320 to avoid short-circuiting between the anodes 321. Each sub-pixel 320 is a color pixel. In the embodiments, the three sub-pixels 320 of different colors included in each pixel unit 32 are a red pixel, a blue pixel, and a green pixel. The blue pixel is located within the third pixel holding region 60, one of the red pixel and the green pixel is located within the first pixel holding region 40, and the other is located within the second pixel holding region 50.

It should be understood that in other embodiments, the three sub-pixels 320 of different colors included in each pixel unit 32 may be of other colors. Any one of the three sub-pixels 320 is disposed within the third pixel holding region 60, and the other two are disposed within the first pixel holding region 40 and the second pixel holding region 50, respectively.

The pixel defining layer 20 defines multiple spaced pixel openings 21 on a side away from the driving substrate 10, and each pixel openings 21 is arranged directly opposite a corresponding pixel holding region. A positive projection of the corresponding pixel holding region on the driving substrate 10 covers a positive projection of the pixel opening 21 on the driving substrate 10. The sub-pixels 320 are provided in one-to-one correspondence with the pixel openings 21, and a portion of the sub-pixel 320 is disposed within the corresponding pixel opening 21. A pitch D between the pixel openings 21 is greater than or equal to 9 micrometers.

That is, a positive projection area of the pixel holding region on the driving substrate 10 is greater than or equal to a positive projection area of the corresponding pixel opening 21 on the driving substrate 10. The electrically conductive isolation structure 31 is arranged on a side of the pixel defining layer 20 away from the driving substrate 10 and between the pixel openings 21. The pixel holding regions enclosed by the electrically conductive isolation structure 31 enclose the corresponding pixel openings 21 and further enclose the sub-pixels 320 disposed within the corresponding pixel openings 21. The pitch D between the pixel openings 21 is greater than or equal to 9 micrometers to reserve space to prepare the electrically conductive isolation structure 31 on the pixel defining layer 20.

The pixel opening 21 exposes a portion of the anode 321 of the sub-pixel 320, and the light emitting layer 322 of the sub-pixel 320 is disposed partially within the pixel opening 21 and partially extends along a side wall of the pixel opening 21. The cathode 323 of the sub-pixel 320 is partially disposed within the pixel opening 21 and partially extends along the side wall of the pixel opening 21 to contact the first electrically conductive isolation structure 311 for electrical conduction. The cathode 323 covers the light emitting layer 322. Each pixel opening 21 is arranged with a sub-pixel 320 and opposite to a pixel holding region. A portion of the sub-pixel 320 is disposed within the pixel opening 21 and the other portion is disposed within the pixel holding region.

It should be understood that a light emitting area of the sub-pixel 320 refers to an area of the portion of the sub-pixel 320 disposed in the pixel opening 21, i.e., the light emitting area of the sub-pixel 320 is the area of the portion of the anode 321 of the sub-pixel 320 exposed from the pixel opening 21.

Further, in each repeating unit 30 and in a plane parallel to the driving substrate 10, a ratio of a sum of the area of the first electrically conductive isolation structure 311 and the area of the second electrically conductive isolation structure 312 to a sum of the light emitting areas of the sub-pixels 320 in the respective pixel holding regions is 3/7. In the related art, the spacing between the sub-pixels 320 is generally greater than 22 micrometers, and the pixel opening ratio is generally 20%. In contrast, this design approach of the present disclosure allows the pixel opening ratio to be increased to 70%. That is, the structural design of the present disclosure may lead to a significant improvement in the pixel opening ratio.

Each repeating unit 30 includes an electrically conductive isolation structure 31 and a pixel unit 32.

In each repeating unit 30, the first electrically conductive isolation structure 311 includes an annular portion 3111 and a dividing portion 3113, and the dividing portion 3113 divides the annular portion 3111 into two sub-annular portions 3112; the two sub-annular portions 3112 enclose to form the first pixel holding region 40 and the second pixel holding region 50. It can be understood that the dividing portion 3113 is disposed within a region enclosed by the annular portion 3111, and both ends of the dividing portion 3113 are connected to inner side walls of the annular portion 3111, such that a portion of the annular portion 3111 forms one sub-annular portion 3112 with the dividing portion 3113, and the other portion of the annular portion 3111 forms the other sub-annular portion 3112 with the dividing portion 3113. That is, the dividing portion 3113 divides the region enclosed by the annular portion 3111 into two spaced apart regions, the two spaced apart regions being the first pixel holding region 40 and the second pixel holding region 50, respectively.

The region enclosed by the annular portion 3111 may be in the shape of a rectangle, a parallelogram, a circle, a trapezoid, a semicircle, or a rhombus, etc., and it should be understood that the region enclosed by the annular portion 3111 may be in the shape of a regular pattern or an irregular pattern. The shape and size of the region enclosed by the annular portion 3111 are not limited herein and are selected according to actual needs.

In each repeating unit 30, the pixel holding regions enclosed by the two sub-annular portions 3112 may have the same shape and/or size, or may have different shapes and sizes. The size and shape of the pixel holding regions enclosed by the two sub-annular portions 3112 in each repeating unit 30 are not limited herein, and are selected according to actual needs.

It should be noted that “A and/or B” in the present disclosure refers to only including A, or only including B, or including both A and B.

It should be understood that the shape and size of the sub-annular portion 3112 determines the shape and size of the pixel holding region formed by the enclosure of the sub-annular portion 3112, which in turn determines the shape and size of the sub pixel 320 disposed within the pixel holding region. That is, the shapes and sizes of the first pixel holding region 40 and the second pixel holding region 50 are determined by the shapes and sizes of the sub-annular portions 3112. The shape and size of the sub-pixel 320 are determined by the shape and size of the pixel holding region in which the sub-pixel 320 is located.

In the embodiments, the region enclosed by the annular portion 3111 is rectangular. In each repeating unit 30, the pixel holding regions enclosed by the two sub-annular portions 3112 are equal in size and shape, and both are rectangular. That is, the first pixel holding region 40 and the second pixel holding region 50 are equal in size and shape.

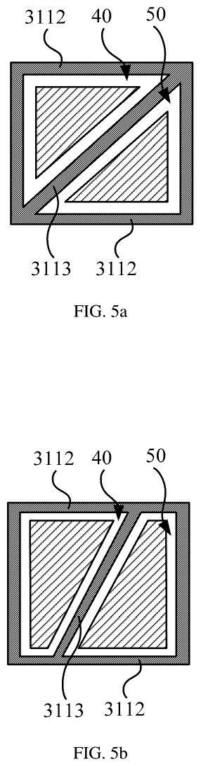

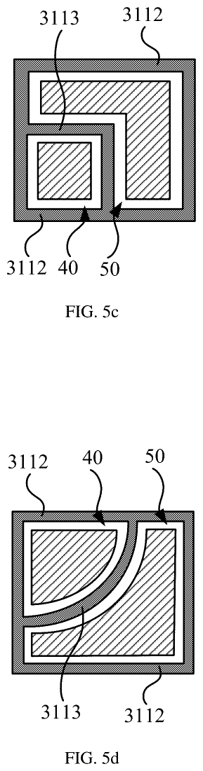

Referring to FIGS. 1, 2, and 5a to 5f, FIG. 5a is a schematic structural view of a first electrically conductive isolation structure and a sub-pixel according to a second embodiment of the present disclosure, FIG. 5b is a schematic structural view of a first electrically conductive isolation structure and a sub-pixel according to a third embodiment of the present disclosure, FIG. 5c is a schematic structural view of a first electrically conductive isolation structure and a sub-pixel according to a fourth embodiment of the present disclosure, FIG. 5d is a schematic structural view of a first electrically conductive isolation structure and a sub-pixel according to a fifth embodiment of the present disclosure, FIG. 5e is a schematic structural view of a first electrically conductive isolation structure and a sub-pixel according to a sixth embodiment of the present disclosure, and FIG. 5f is a schematic structural view of a first electrically conductive isolation structure and a sub-pixel according to a seventh embodiment of the present disclosure

In other embodiments, the region enclosed by the annular portion 3111 may be of other shapes such as a parallelogram, an oval, etc., and the sub-annular portion 3112 may be of other shapes such as a parallelogram, a triangle, etc. The two sub-annular portions 3112 in each repeating unit 30 may have the same shape and/or size, or neither may be the same.

Further, the second electrically conductive isolation structure 312 is disposed on at least one side of the first electrically conductive isolation structure 311. The third pixel holding region 60 is disposed on the side of the second electrically conductive isolation structure 312 toward the first electrically conductive isolation structure 311. The third pixel holding region 60 half encloses the first electrically conductive isolation structure 311, or the third pixel holding region 60 fully encloses the first electrically conductive isolation structure 311.

When the second electrically conductive isolation structure 312 is disposed on a side of the first electrically conductive isolation structure 311, the second electrically conductive isolation structure 312 is a strip structure. When the second electrically conductive isolation structure 312 is disposed on at least two sides of the first electrically conductive isolation structure 311, the second electrically conductive isolation structure 312 half encloses the first electrically conductive isolation structure 311 or fully encloses the first electrically conductive isolation structure 311.

It should be understood that the cathode 323 of the sub-pixel 320 disposed within the third pixel holding region 60 may further be in contact with and electrically conductive with the second electrically conductive isolation structure 312. That is, the cathode 323 of the sub-pixel 320 disposed within the third pixel holding region 60 may be in contact with and electrically conductive to the first electrically conductive isolation structure 311 and/or the second electrically conductive isolation structure 312.

The third pixel holding region 60 is disposed on the side of the second electrically conductive isolation structure 312 toward the first electrically conductive isolation structure 311, that is, the third pixel holding region 60 and the first electrically conductive isolation structure 311 are disposed on the same side of the second electrically conductive isolation structure 312, so as to better enclose the first electrically conductive isolation structure 311 by the third pixel holding region 60.

When the third pixel holding region 60 half encloses the first electrically conductive isolation structure 311, the third pixel holding region 60 is a C-shaped structure or an L-shaped structure. When the third pixel holding region 60 fully encloses the first electrically conductive isolation structure 311, the third pixel holding region 60 is an annular structure, which may be a closed annular structure or an open annular structure. The third pixel holding region 60 being a closed annular structure or an open annular structure depends on how the first electrically conductive isolation structure 311 and the second electrically conductive isolation structure 312 are electrically connected.

In the embodiments, the third pixel holding region 60 half encloses the first electrically conductive isolation structure 311, and the third pixel holding region 60 is provided in a C-shaped structure. The first electrically conductive isolation structure 311 is in direct contact and electrically conductive with the second electrically conductive isolation structure 312, and in each electrically conductive isolation structure 31, a side edge of the first electrically conductive isolation structure 311 near the second electrically conductive isolation structure 312 serves as a portion of the second electrically conductive isolation structure 312. It is to be understood that in a direction perpendicular to the driving substrate 10, the side edge of the first electrically conductive isolation structure 311 near the second electrically conductive isolation structure 312 is disposed partially overlapping with the second electrically conductive isolation structure 312, and the structure in an overlapping region serves as both a portion of the first electrically conductive isolation structure 311 and a portion of the second electrically conductive isolation structure 312. That is, the first electrically conductive isolation structure 311 and the second electrically conductive isolation structure 312 share the structure in the overlapping region. This design approach may reduce the spacing between the first electrically conductive isolation structure 311 and the second electrically conductive isolation structure 312, which is conducive to enhancing the pixel opening ratio.

In the present embodiments, the side edge of the first electrically conductive isolation structure 311 near the second electrically conductive isolation structure 312 serves as a portion of the second electrically conductive isolation structure 312, which not only allows the first electrically conductive isolation structure 311 and the second electrically conductive isolation structure 312 to be set up for electrical conduction by contacting, but also reduces the spacing between the first electrically conductive isolation structure 311 and the second electrically conductive isolation structure 312, thereby reducing spacing between the repeating units 30, such that the pixel opening ratio may be increased.

Further, in the embodiments, the repeating units 30 are arranged in an array. In a row direction of the repeating units 30, the first electrically conductive isolation structure 311 and the second electrically conductive isolation structure 312 are arranged alternately. In a column direction of the repeating units 30, adjacent third pixel holding regions 60 are spaced apart from each other, and adjacent second electrically conductive isolation structures 312 are electrically connected to each other. In the row direction of the repeating units 30, the multiple repeating units 30 are electrically accessed to the same electrical signal through the second electrically conductive isolation structures 312. The first direction is the column direction of the repeating units 30, i.e., the first direction is both the extension direction of the second electrically conductive isolation structure 312 and the column direction of the repeating units 30.

In the embodiments, the display panel further includes a binding portion (not shown) extending along the row direction of the repeating units 30, and the binding portion is configured to be connected to the second electrically conductive isolation structures 312 in a first row of the repeating units 30 or a last row of the repeating units 30, so as to realize the mutual electrically connection of the second electrically conductive isolation structures 312 of the multiple columns of the repeating units 30. The second electrically conductive isolation structures 312 of the multiple columns of repeating units 30 are accessed to the same electrical signal through the binding portion.

It should be understood that the display panel may not include a binding portion. Since the second electrically conductive isolation structures 312 in each column of repeating units 30 are electrically connected to each other, the second electrically conductive isolation structures 312 in the first row of repeating units 30 or in the last row of repeating units 30 may be accesses to the same electrical signal, such that the second electrically conductive isolation structures 312 of all the repeating units 30 are accessed to the same electrical signal.

The electrically conductive isolation structure 31 includes an electrically conductive portion 314 and an insulating top portion 315 disposed on an upper surface of the electrically conductive portion 314 and obscuring the electrically conductive portion 314. In each repeating unit 30, the cathode 323 of the sub-pixel 320 is in contact with the electrically conductive portion 314 of the first electrically conductive isolation structure 311.

A portion of the insulating top portion 315 is arranged in an overhanging setting with respect to the electrically conductive portion 314. The overhanging portion may adjust the vaporization angle of the light emitting layer 322 and the cathode 323, which facilitates the cathode 323 to cover the light emitting layer 322. The insulating top portion 315 is further configured to isolate the sub-pixel 320.

It should be understood that the first electrically conductive isolation structure 311 includes the electrically conductive portion 314 and the insulating top portion 315 disposed on an upper surface of the electrically conductive portion 314 and obscuring the electrically conductive portion 314. The second electrically conductive isolation structure 312 includes the electrically conductive portion 314 and the insulating top portion 315 disposed on an upper surface of the electrically conductive portion 314 and obscuring the electrically conductive portion 314.

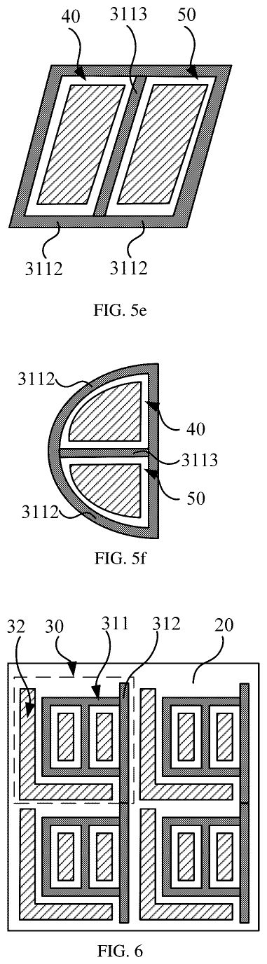

Referring to FIGS. 1, 2, 3, and 6, FIG. 6 is a structural schematic view of a display panel according to a second implementation of the present disclosure.

The second implementation of the display panel provided in the present disclosure has essentially the same structure as compared to the first implementation of the display panel provided in the present disclosure, with the difference that the third pixel holding region 60 half encloses the first electrically conductive isolation structure 311, and the third pixel holding region 60 is in an L-shaped structure.

In the present embodiments, the third pixel holding region 60 half encloses the first electrically conductive isolation structure 311, and the third pixel holding region 60 is arranged in an L-shaped structure.

The present embodiments may also enhance the pixel opening ratio and mitigate the problem of colored edges of the display panel.

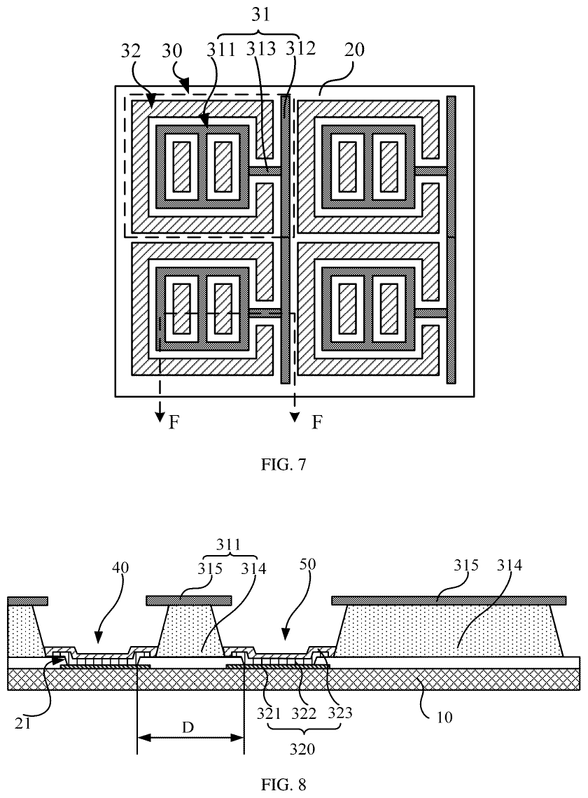

Referring to FIGS. 1, 2, 3, 7, and 8, FIG. 7 is a structural schematic view of a display panel according to a third implementation of the present disclosure, and FIG. 8 is a cross-sectional structural schematic view along F-F in FIG. 7.

The third implementation of the display panel provided in the present disclosure has essentially the same structure as compared to the first implementation of the display panel provided in the present disclosure, with the difference that the electrically conductive isolation structure 31 further includes a lap electrically conductive isolation structure 313 disposed between the first electrically conductive isolation structure 311 and the second electrically conductive isolation structure 312. The first electrically conductive isolation structure 311 and the second electrically conductive isolation structure 312 are electrically connected through the lap electrically conductive isolation structure 313.

In the embodiments, the electrically conductive isolation structure 31 further includes the lap electrically conductive isolation structure 313 disposed between the first electrically conductive isolation structure 311 and the second electrically conductive isolation structure 312. The first electrically conductive isolation structure 311 and the second electrically conductive isolation structure 312 are electrically connected by the lap electrically conductive isolation structure 313. That is, the first electrically conductive isolation structure 311 and the second electrically conductive isolation structure 312 are spaced apart, with an end of the lap electrically conductive isolation structure 313 being connected to the first electrically conductive isolation structure 311 and the other end of the lap electrically conductive isolation structure 313 being connected to the second electrically conductive isolation structure 312, to conduct the first electrically conductive isolation structure 311 and the second electrically conductive isolation structure 312.

Further, the lap electrically conductive isolation structure 313 may be arranged perpendicular to the second electrically conductive isolation structure 312, or may be inclined to the second electrically conductive isolation structure 312. The end of the lap electrically conductive isolation structure 313 being connected to the first electrically conductive isolation structure 311 may be connected to the annular portion 3111 and/or the dividing portion 3113.

In the embodiments, the lap electrically conductive isolation structure 313 is arranged perpendicular to the second electrically conductive isolation structure 312 and is connected to the annular portion 3111. The third pixel holding region 60 is an open annular structure. The lap electrically conductive isolation structure 313 is disposed at an opening of the open annular structure.

It should be noted that the lap electrically conductive isolation structure 313 also includes an electrically conductive portion 314 and an insulating top portion 315 disposed on an upper surface of the electrically conductive portion 314 and obscuring the electrically conductive portion 314.

The present embodiments may also enhance the pixel opening ratio and mitigate the problem of colored edges of the display panel.

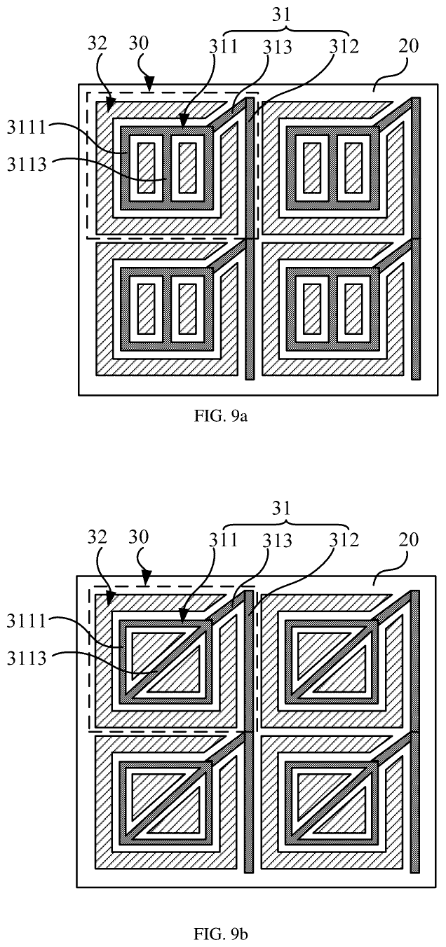

Referring to FIGS. 1, 2, 3, 9a, and 9b, FIG. 9a is a structural schematic view of a display panel according to a fourth implementation of the present disclosure, and FIG. 9b is a structural schematic view of a display panel according to a fifth implementation of the present disclosure.

It should be understood that in other embodiments, the lap electrically conductive isolation structure 313 is inclined to the second electrically conductive isolation structure 312. The end of the lap electrically conductive isolation structure 313 being connected to the first electrically conductive isolation structure 311 may be connected to the annular portion 3111, or it may be connected to both the annular portion 3111 and the dividing portion 3113.

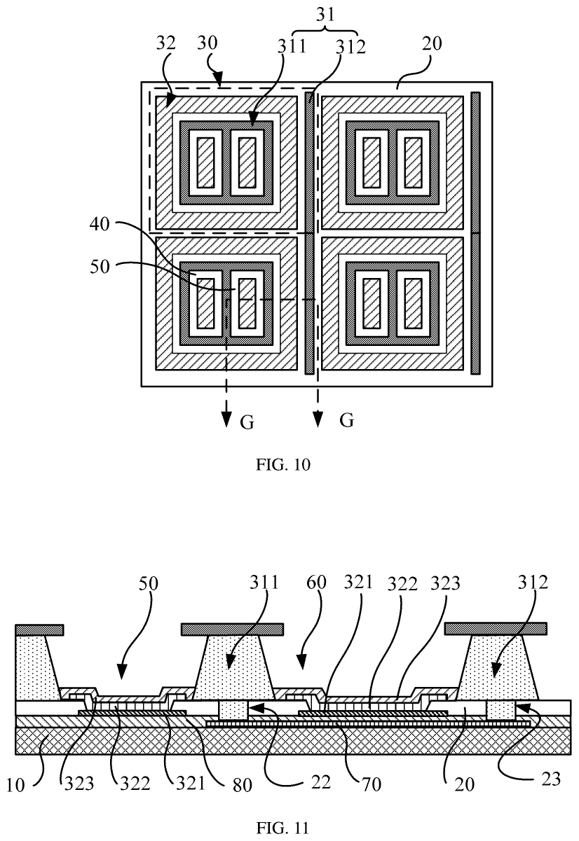

Referring to FIGS. 1, 2, 3, 10, and 11, FIG. 10 is a structural schematic view of a display panel according to a sixth implementation of the present disclosure, and FIG. 11 is a cross-sectional structural schematic view along G-G in FIG. 10.

The sixth implementation of the display panel provided in the present disclosure has essentially the same structure as compared to the first implementation of the display panel provided in the present disclosure, with the difference that the display panel further includes an auxiliary electrode 70 disposed on a side of the sub-pixel 320 near the driving substrate 10. In each electrically conductive isolation structure 31, the first electrically conductive isolation structure 311 and the second electrically conductive isolation structure 312 are connected respectively to the auxiliary electrode 70 through openings, such that the first electrically conductive isolation structure 311 and the second electrically conductive isolation structure 312 are electrically connected through the auxiliary electrode 70.

In the embodiments, the display panel further includes the auxiliary electrode 70 disposed on a side of the sub-pixel 320 near the driving substrate 10. The display panel further includes an insulating layer 80, the insulating layer 80 being disposed between the sub-pixel 320 and the auxiliary electrode 70 and covering the auxiliary electrode 70. The insulating layer 80 is configured to isolate the anode 321 and the auxiliary electrode 70 in order to avoid a short circuit in the anode 321. In each electrically conductive isolation structure 31, the first electrically conductive isolation structure 311 and the second electrically conductive isolation structure 312 are connected to the auxiliary electrode 70 through openings to electrically connect the first electrically conductive isolation structure 311 to the second electrically conductive isolation structure 312 via the auxiliary electrode 70, respectively. The first electrically conductive isolation structure 311 and the second electrically conductive isolation structure 312 are spaced apart. The third pixel holding region 60 may be a closed annular structure.

In the direction perpendicular to the driving substrate 10, the first electrically conductive isolation structure 311 is partially overlapped with the auxiliary electrode 70, and, the second electrically conductive isolation structure 312 is partially overlapped with the auxiliary electrode 70, so as to facilitate the first electrically conductive isolation structure 311 to be connected to the auxiliary electrodes 70 through a corresponding opening and the second electrically conductive isolation structure 312 to be connected to the auxiliary electrodes 70 through a corresponding opening. The auxiliary electrode 70 is disposed between the sub-pixel 320 and the driving substrate 10.

Further, the pixel defining layer 20 includes a first opening 22 and a second opening 23. The first opening 22 is arranged directly opposite the electrically conductive portion 314 of the first electrically conductive isolation structure 311, and the second opening 23 is arranged directly opposite the electrically conductive portion 314 of the second electrically conductive isolation structure 312, so as to facilitate the direct passage of the first electrically conductive isolation structure 311 through the pixel defining layer 20 directly below the electrically conductive portion 314 to connect to the auxiliary electrode 70 as well as to facilitate the direct passage of the second electrically conductive isolation structure 312 through the pixel defining layer 20 directly below the electrically conductive portion 314 to connect to the auxiliary electrode 70. In addition, setting the first opening 22 and the second opening 23 directly opposite the electrically conductive portion 314 of the first electrically conductive isolation structure 311 and the electrically conductive portion 314 of the second electrically conductive isolation structure 312, respectively, avoids that the first opening 22 and the second opening 23 take up additional spacing between the sub-pixels 320, which is conducive to improving the pixel opening ratio.

Compared to the third implementation of the display panel provided in the present disclosure, the spacing between the first electrically conductive isolation structure 311 and the second electrically conductive isolation structure 312 spaced apart in the present embodiments may be less, which is more conducive to improving the pixel opening ratio, in addition to which the present embodiments may also mitigate the problem of colored edges of the display panel.

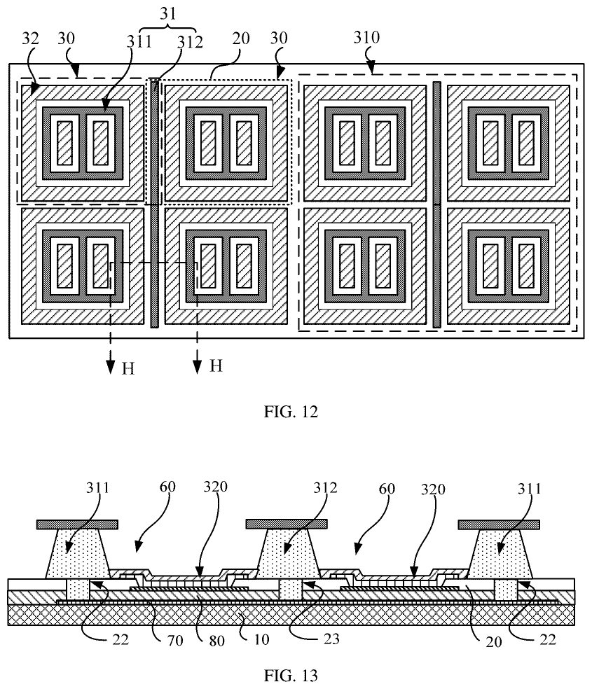

Referring to FIGS. 1, 2, 3, and 10 to 13, FIG. 12 is a structural schematic view of a display panel according to a seventh implementation of the present disclosure, and FIG. 13 is a cross-sectional structural schematic view along H-H in FIG. 12.

The seventh implementation of the display panel provided by the present disclosure has essentially the same structure as compared to the fourth implementation of the display panel provided by the present disclosure, with the difference that the display panel further includes multiple repeating unit groups 310 repetitively arranged along the row direction of the repeating units 30, and each repeating unit group 310 includes two adjacent rows of electrically conductive isolation structures 31. In each repeating unit group 310, two electrically conductive isolation structures 31 provided adjacent to each other in the row direction of the repeating units 30 share the same second electrically conductive isolation structure 312.

In this embodiment, the display panel further comprises multiple repeating unit groups 310 repetitively arranged along the row direction of the repeating unit 30, and each repeating unit group 310 comprises two adjacent columns of the electrically conductive isolation structures 31. In each repeating unit group 310, the two electrically conductive isolation structures 31 arranged adjacent to each other in the row direction of the repeating unit 30 share a same second electrically conductive isolation structure 312.

In each repeating unit group 310, the two electrically conductive isolation structures 31 arranged adjacent to each other in the row direction of the repeating units 30 share the same second electrically conductive isolation structure 312, which may reduce the second electrically conductive isolation structure 312 by half compared to the third implementation of the display panel provided in the present disclosure, thereby reducing the number of the second openings 23 by half, and thereby facilitating the preparation of the display panel.

The present embodiments may also enhance the pixel opening ratio and mitigate the problem of colored edges of the display panel.

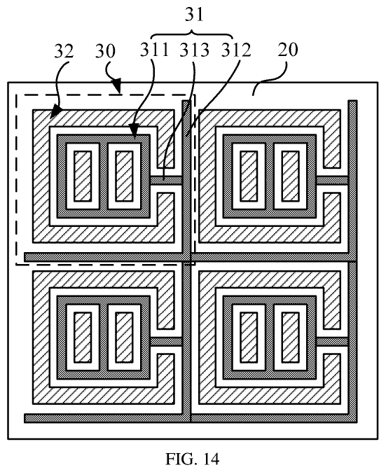

Referring to FIGS. 1, 2, 3, 7, and 14, FIG. 14 is a structural schematic view of a display panel according to an eighth implementation of the present disclosure.

The eighth implementation of the display panel provided in the present disclosure has essentially the same structure as compared to the third implementation of the display panel provided in the present disclosure, with the difference that in each repeating unit 30, the second electrically conductive isolation structure 312 is disposed on adjacent sides of the first electrically conductive isolation structure 311.

In the embodiments, in each repeating unit 30, the second electrically conductive isolation structure 312 is disposed on adjacent sides of the first electrically conductive isolation structure 311. The second electrically conductive isolation structure 312 is in an L-shaped structure.

In the row direction of the repeating unit 30, the second electrically conductive isolation structures 312 in two adjacent repeating units 30 are in contact and electrically conductive with each other, such that the second electrically conductive isolation structures 312 in the two adjacent repeating units 30 are electrically connected, thereby realizing the mutual electrically connection of the second electrically conductive isolation structures 312 of the multiple columns of repeating units 30.

It should be understood that the present embodiments do not require a binding portion to realize the mutual electrically connection of the second electrically conductive isolation structures 312 of the multiple columns of repeating units 30.

The present embodiments may also enhance the pixel opening ratio and mitigate the problem of colored edges of the display panel.

The present disclosure further provides a display device, the display device including a display panel as described above. The display panel is an OLED display panel.

In the above embodiments, the description of each embodiment has its own focus, and the part that is not described in detail in any embodiment may be referred to the relevant description of other embodiments.

The above is only some embodiments of the present disclosure, and is not intended to limit the scope of the present disclosure. Any equivalent structure or equivalent process transformation utilizing the contents of the specification of the present disclosure and the accompanying drawings, or directly or indirectly utilized in other related technical fields, are all reasonably included in the scope of the present disclosure.

What is claimed is:

1. A display panel, comprising:
a driving substrate;
a pixel defining layer, arranged on a side of the driving substrate; and
a plurality of repeating units; wherein each repeating unit comprises:
an electrically conductive isolation structure, comprising a first electrically conductive isolation structure and a second electrically conductive isolation structure electrically connected to each other; wherein the first electrically conductive isolation structure protrudes out of the pixel defining layer and encloses to form a first pixel holding region and a second pixel holding region that are spaced apart; the second electrically conductive isolation structure is disposed on at least one side of the first electrically conductive isolation structure, and a side of the second electrically conductive isolation structure toward the first electrically conductive isolation structure is formed with a third pixel holding region at least partially enclosing the first electrically conductive isolation structure; and
a pixel unit, comprising three sub-pixels having different colors; wherein the three sub-pixels are disposed in a one-to-one correspondence in the first pixel holding region, the second pixel holding region, and the third pixel holding region formed in the electrically conductive isolation structure;
wherein in each repeating unit, a cathode of each of the three sub-pixels is in contact and electrically conductive with the first electrically conductive isolation structure; the second electrically conductive isolation structure extends along a first direction, and multiple of the plurality of repeating units are arranged in an array along the first direction; the multiple of the plurality of repeating units are electrically connected to each other through the second electrically conductive isolation structures and accessed to a same electrical signal.

2. The display panel according to claim 1, wherein the first electrically conductive isolation structure comprises an annular portion and a dividing portion, and the dividing portion divides the annular portion into two sub-annular portions; the two sub-annular portions enclose to form the first pixel holding region and the second pixel holding region.

3. The display panel according to claim 2, wherein the third pixel holding region half encloses the first electrically conductive isolation structure, or the third pixel holding region fully encloses the first electrically conductive isolation structure.

4. The display panel according to claim 2, wherein the first electrically conductive isolation structure is in direct contact and electrically conductive with the second electrically conductive isolation structure, and a side edge of the first electrically conductive isolation structure near the second electrically conductive isolation structure serves as a portion of the second electrically conductive isolation structure.

5. The display panel according to claim 2, wherein the electrically conductive isolation structure further comprises a lap electrically conductive isolation structure disposed between the first electrically conductive isolation structure and the second electrically conductive isolation structure; the first electrically conductive isolation structure and the second electrically conductive isolation structure are electrically connected through the lap electrically conductive isolation structure.

6. The display panel according to claim 5, wherein the lap electrically conductive isolation structure is perpendicular to the second electrically conductive isolation structure, and an end of the lap electrically conductive isolation structure being connected to the first electrically conductive isolation structure is connected to the annular portion and/or the dividing portion.

7. The display panel according to claim 6, wherein the third pixel holding region is an open annular structure, and the lap electrically conductive isolation structure is disposed at an opening of the open annular structure.

8. The display panel according to claim 6, wherein the display panel further comprises an auxiliary electrode disposed on a side of the sub-pixel near the driving substrate; in each electrically conductive isolation structure, the first electrically conductive isolation structure and the second electrically conductive isolation structure are connected respectively to the auxiliary electrode; the first electrically conductive isolation structure and the second electrically conductive isolation structure are electrically connected through the auxiliary electrode.

9. The display panel according to claim 8, wherein the pixel defining layer comprises a first opening and a second opening; the first opening is arranged directly opposite the first electrically conductive isolation structure, and the second opening is arranged directly opposite the second electrically conductive isolation structure; the first electrically conductive isolation structure is connected respectively to the auxiliary electrode through the first opening, and the second electrically conductive isolation structure is connected respectively to the auxiliary electrode through the second opening.

10. The display panel according to claim 2, wherein the plurality of repeating units are arranged in an array; in a row direction of the plurality of repeating units, the first electrically conductive isolation structure and the second electrically conductive isolation structure are arranged alternately to form a sequence of: the first electrically conductive isolation structure, the second electrically conductive isolation structure, the first electrically conductive isolation structure, the second electrically conductive isolation structure, etc.

11. The display panel according to claim 10, wherein in a column direction of the plurality of repeating units, two the third pixel holding regions that are adjacent to each other are spaced apart from each other, and two the second electrically conductive isolation structures that are adjacent to each other are electrically connected to each other; in the row direction of the plurality of repeating units, the plurality of repeating units are electrically accessed to the same electrical signal through the second electrically conductive isolation structures; wherein the first direction is the column direction of the plurality of repeating units.

12. The display panel according to claim 2, wherein the display panel further comprises a plurality of repeating unit groups repetitively arranged along a row direction of the plurality of repeating units, and each repeating unit group comprises two adjacent rows of the electrically conductive isolation structures; in each repeating unit group, two the electrically conductive isolation structures that are adjacent to each other in the row direction of the plurality of repeating units share a same corresponding second electrically conductive isolation structure

13. The display panel according to claim 1, wherein in each repeating unit and in a plane parallel to the driving substrate, a ratio of a sum of an area of the first electrically conductive isolation structure and an area of the second electrically conductive isolation structure to a sum of light emitting areas of the three sub-pixels is 3/7.

14. The display panel according to claim 1, wherein the pixel defining layer defines a plurality of spaced pixel openings on a side away from the driving substrate; for each pixel openings, the pixel opening is arranged directly opposite a corresponding pixel holding region among the first pixel holding region, the second pixel holding region, and the third pixel holding region; a positive projection of the corresponding pixel holding region on the driving substrate covers a positive projection of the pixel opening on the driving substrate; the sub-pixels of the plurality of repeating units are provided in one-to-one correspondence with the pixel openings, and a portion of each sub-pixel is disposed within a corresponding pixel opening; a pitch between each adjacent two of the plurality of pixel openings is greater than or equal to 9 micrometers.

15. The display panel according to claim 14, wherein for each sub-pixel, the sub-pixel comprises an anode, a light emitting layer, and a cathode sequentially cascaded on the side of the driving substrate;
a corresponding pixel opening opposite the sub-pixel exposes a portion of the anode, and the light emitting layer is disposed partially within the pixel opening and partially extends along a side wall of the pixel opening; the cathode is partially disposed within the pixel opening and partially extends along the side wall of the pixel opening to contact the first electrically conductive isolation structure for electrical conduction.

16. The display panel according to claim 1, wherein the electrically conductive isolation structure comprises an electrically conductive portion and an insulating top portion disposed on an upper surface of the electrically conductive portion and obscuring the electrically conductive portion; a cathode of each sub-pixel is in contact with the electrically conductive portion of the first electrically conductive isolation structure.

17. The display panel according to claim 16, wherein a portion of the insulating top portion is arranged in an overhanging setting with respect to the electrically conductive portion.

18. The display panel according to claim 1, wherein the second electrically conductive isolation structure is disposed on adjacent sides of the first electrically conductive isolation structure.

19. A display device, comprising a display panel:
wherein the display panel comprises:
a driving substrate;
a pixel defining layer, arranged on a side of the driving substrate; and
a plurality of repeating units; wherein each repeating unit comprises:
an electrically conductive isolation structure, comprising a first electrically conductive isolation structure and a second electrically conductive isolation structure electrically connected to each other; wherein the first electrically conductive isolation structure protrudes out of the pixel defining layer and encloses to form a first pixel holding region and a second pixel holding region that are spaced apart; the second electrically conductive isolation structure is disposed on at least one side of the first electrically conductive isolation structure, and a side of the second electrically conductive isolation structure toward the first electrically conductive isolation structure is formed with a third pixel holding region at least partially enclosing the first electrically conductive isolation structure; and
a pixel unit, comprising three sub-pixels having different colors; wherein the three sub-pixels are disposed in a one-to-one correspondence in the first pixel holding region, the second pixel holding region, and the third pixel holding region formed in the electrically conductive isolation structure;
wherein in each repeating unit, a cathode of each of the three sub-pixels is in contact and electrically conductive with the first electrically conductive isolation structure; the second electrically conductive isolation structure extends along a first direction, and multiple of the plurality of repeating units are arranged in an array along the first direction; the multiple of the plurality of repeating units are electrically connected to each other through the second electrically conductive isolation structures and accessed to a same electrical signal.

20. The display device according to claim 19, wherein the first electrically conductive isolation structure comprises an annular portion and a dividing portion, and the dividing portion divides the annular portion into two sub-annular portions; the two sub-annular portions enclose to form the first pixel holding region and the second pixel holding region.
